(19) United States
(12) Patent Application Publication
(10) Pub. No.: US 2016/0284640 A1
(43) Pub. Date: Sep. 29, 2016

(54) SEMICONDUCTOR DEVICE HAVING BURIED WORDLINES

(71) Applicant: INOTERA MEMORIES, INC., Taoyuan City (TW)

(72) Inventors: Kuo-Chen Wang, New Taipei City (TW); Vishnu Kumar Agarwal, Bristow, VA (US)

(21) Appl. No.: 14/668,971

(22) Filed: Mar. 25, 2015

(51) Int. Cl. H01L 23/522; H01L 23/528; H01L 23/532; H01L 27/02

(52) U.S. Cl. CPC H01L 23/5223; H01L 27/0207; H01L 23/5283; H01L 23/53204

(57) ABSTRACT

A memory device includes a substrate having thereon a plurality of active areas that are isolated from one another by a shallow trench isolation (STI) region. A plurality of digitlines is arranged along a first direction on the substrate. A plurality of buried wordlines is arranged in wordline trenches in the substrate along a second direction that is orthogonal to the first direction. A plurality of thicker portions and thinner portions are alternately and repeatedly arranged in each of the wordline trenches to thereby constitute each of the buried wordlines. Each of the thinner portions is arranged between two ends of adjacent two of the active areas.

### BACKGROUND OF THE INVENTION

1. Field of the Invention

The present invention relates to a highly integrated semiconductor device, and more particularly, to a semiconductor memory device having buried wordlines and a fabrication method thereof.

2. Description of the Prior Art

Buried cell array transistor (BCAT) in which a word line (or gate electrode) is buried in a semiconductor substrate is known in the art.

A BCAT structure allows for word lines to have a pitch (or spacing) of about 0.5 F and helps to minimize the cell area. Also, a buried gate of a BCAT structure may provide a greater effective channel length than a stacked gate or recessed gate.

As the degree of integration of the memory is increased, a pitch of a word line is gradually reduced, resulting in an increase in a coupling effect between word lines and unneglectable gate induced drain leakage (GIDL) current.

When the number of times, by which an activated state and a deactivated state of a word line are toggled, is increased, data of a memory cell connected to an adjacent word line may be damaged due to the coupling effect between word lines. Such a phenomenon is known as a row hammer phenomenon. Further, the GIDL current adversely affects the refresh property of the memory device.

The present invention addresses these prior art problems.

### SUMMARY OF THE INVENTION

It is one object of the invention to provide an improved semiconductor memory device having buried wordlines, which is capable of reducing GIDL current, thereby improving refresh property of the memory device.

According to an aspect of the present invention, there is provided a memory device, comprising a substrate having thereon a plurality of active areas that are isolated from one another by a shallow trench isolation (STI) region; a plurality of digitlines arranged along a first direction on the substrate; and a plurality of buried wordlines arranged in wordline trenches in the substrate along a second direction that is orthogonal to the first direction, wherein a plurality of thicker portions and thinner portions are alternately and repeatedly arranged in each of the wordline trenches to thereby constitute each of the buried wordlines.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The above and other aspects and features of the present invention will become apparent by describing in detail exemplary embodiments thereof with reference to the attached drawings, in which:

FIG. 1 is a plan view depicting one illustrative embodiment of a memory array in accordance with the present invention;

FIG. 2 is a schematic, cross-sectional diagram taken along line I-I′ in FIG. 1;

FIG. 3 is a schematic, cross-sectional diagram taken along line II-II′ in FIG. 1; and

FIG. 4 to FIG. 10 are schematic diagrams depicting an exemplary method for fabricating the memory device having buried wordlines, wherein FIG. 9 and FIG. 10 are aerial views illustrating two types of LRG opening patterns.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following description, numerous specific details are given to provide a thorough understanding of the invention. It will, however, be apparent to one skilled in the art that the invention may be practiced without these specific details. Furthermore, some well-known system configurations and process steps are not disclosed in detail, as these should be well-known to those skilled in the art.

Likewise, the drawings showing embodiments of the apparatus are semi-diagrammatic and not to scale and some dimensions are exaggerated in the figures for clarity of presentation. Also, where multiple embodiments are disclosed and described as having some features in common, like or similar features will usually be described with like reference numerals for ease of illustration and description thereof.

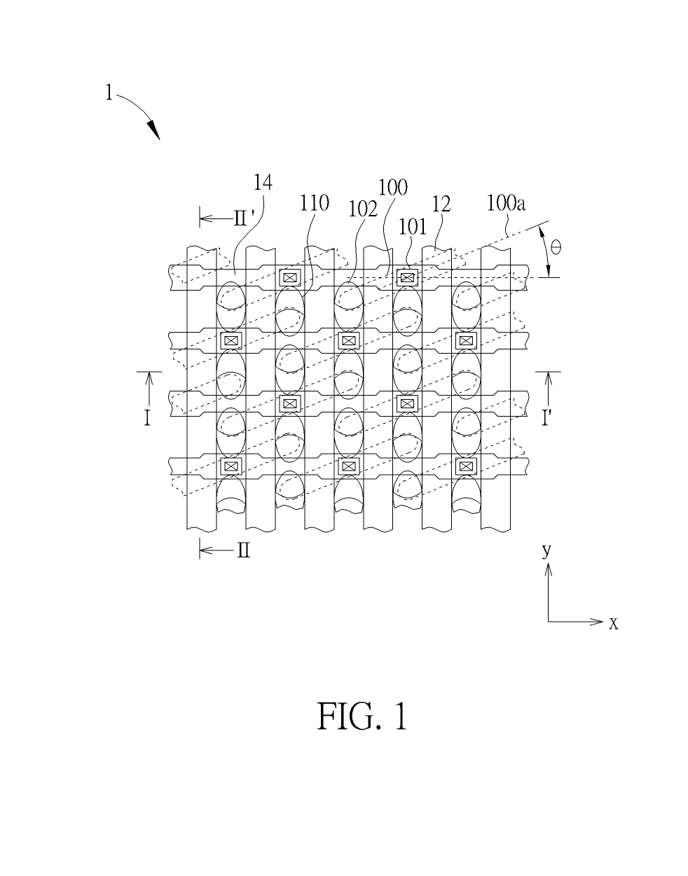

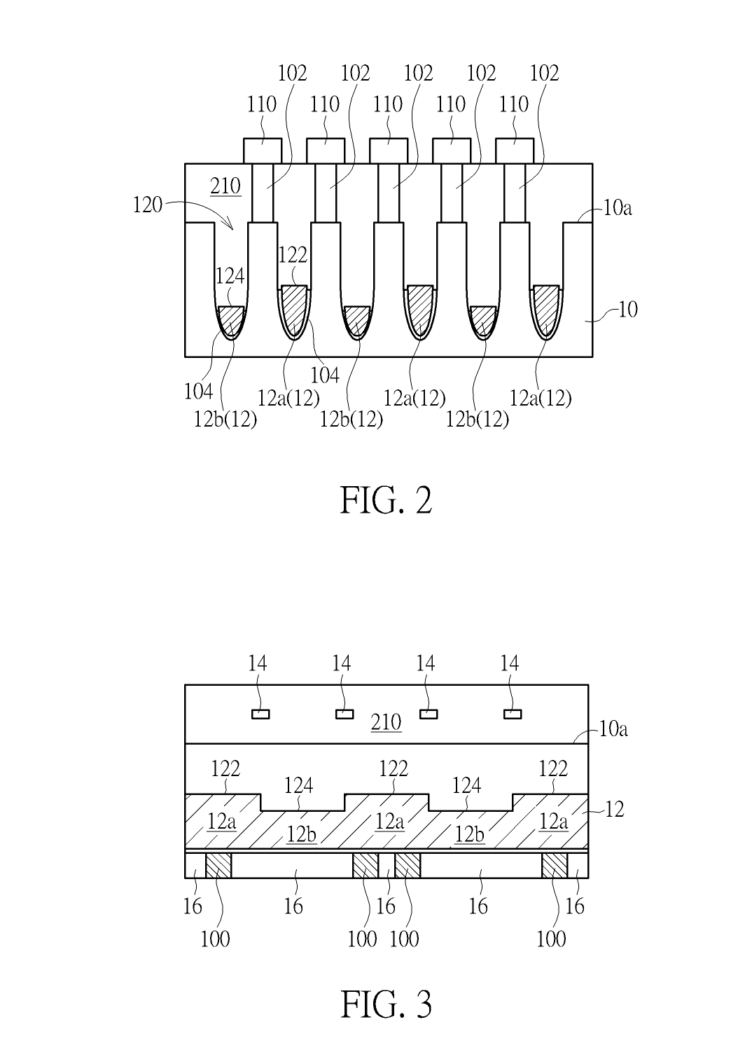

Please refer to FIG. 1 to FIG. 3. FIG. 1 is a plan view depicting one illustrative embodiment of a memory array 1 in accordance with the present invention. FIG. 2 is a schematic, cross-sectional diagram taken along line I-I′ in FIG. 1. FIG. 3 is a schematic, cross-sectional diagram taken along line II-II′ in FIG. 1. As depicted therein, the memory array 1 having an effective 6F² DRAM cell design (3F×2F cell). The 6F² DRAM cell is rectangular and measures 3F in the digitline direction (reference x-axis direction) and 2F in the wordline direction (reference y-axis direction), where F is the half-pitch of the respective lines.

The memory array 1 comprises a plurality of active areas 100 (indicated by dashed lines), buried wordlines 12, and digitlines 14. The buried wordline 12 is physically orthogonal to the digitline 14. The buried wordline 12 may be composed of metal, such as titanium nitride (TiN), tungsten (W), or a combination thereof. Each active area 100 has an approximately longitudinal centerline 100a that is positioned at an angle θ relative to the reference x-axis or the centerline 14a of each of the digitlines 14. The angle θ may vary to some degree. In one exemplary embodiment, the angle θ may range between 20-80 degrees. The active areas 100 are separated silicon portions of a silicon substrate 10, which are isolated from one another by shallow trench isolation (STI) region 16.

According to the illustrative embodiment, the memory array 1 includes a dual memory cell arrangement. According to the illustrative embodiment, each of the active areas 100 is penetrated by two buried wordlines 12 and is therefore a dual bit active area. A single digitline contact 101 is formed on a common source region between the two buried wordlines 12. The dual memory cell arrangement further includes two storage contacts 102 positioned on respective drain regions at distal ends of each active area 100 to electrically couple to respective capacitors 110. It is to be understood that the layout of the memory array 1 is for illustration purposes only. The present invention may be applicable to other memory layouts.

As shown in FIG. 2, the capacitors 110 may be formed on a dielectric layer 210, and the storage contacts 102 may be formed in the dielectric layer 210. The dielectric layer 210 may fill into the wordline trenches 120 to cap the buried wordlines 12. A gate dielectric layer 104 may be formed between the buried wordline and the silicon substrate 10. The gate dielectric layer 104 is conformally formed on interior surface at the lower portion of each of the wordline trenches 120.

According to the illustrative embodiment, the wordline trenches 120 have substantially the same trench depth below a main surface 10a of the silicon substrate 10. The portions of each buried wordline 12 that intersect the active areas 100 act as agate electrode of the RCAT (recess channel array transistor) device, and the portions of the each buried wordline 12 between the adjacent active areas 100 along the wordline direction (reference y-axis direction) act as a passing gate.

According to the illustrative embodiment, as can be best seen in FIG. 2 and FIG. 3, each of the buried wordlines 12 comprises at least two successive and continuous thicker portion 12a and thinner portion 12b. The thicker portion 12a has a thickness that is greater than that of the thinner portion 12b. A plurality of thicker portions 12a and the thinner portions 12b are alternately and repeatedly arranged in each of the wordline trenches 120 to thereby constitute each of the buried wordlines 12.

The thicker portion 12a has a substantially flat top surface 122 and the thinner portion 12b has a substantially flat top surface 124. According to the illustrative embodiment, the top surface 122 is in a higher horizontal level than the top surface 124. According to the illustrative embodiment, both of the top surface 122 and the top surface 124 are lower than the main surface 10a of the silicon substrate 10.

As can be best seen in FIG. 3, each of the buried wordlines 12 composed of a plurality of continuously and repeatedly arranged thicker portion 12a and the thinner portion 12b has a battlement-shaped profile in cross-section observation. According to the illustrative embodiment, the thinner portion 12a is arranged between two ends of two adjacent active areas 100.

By providing the thinner portions 12b in the buried wordlines 12 between the two ends of two adjacent active areas 100, the buried wordlines 12 may underlap with the adjacent drain junction in the drain regions of the active areas, thereby reducing GIDL current and improving refresh property of the memory device.

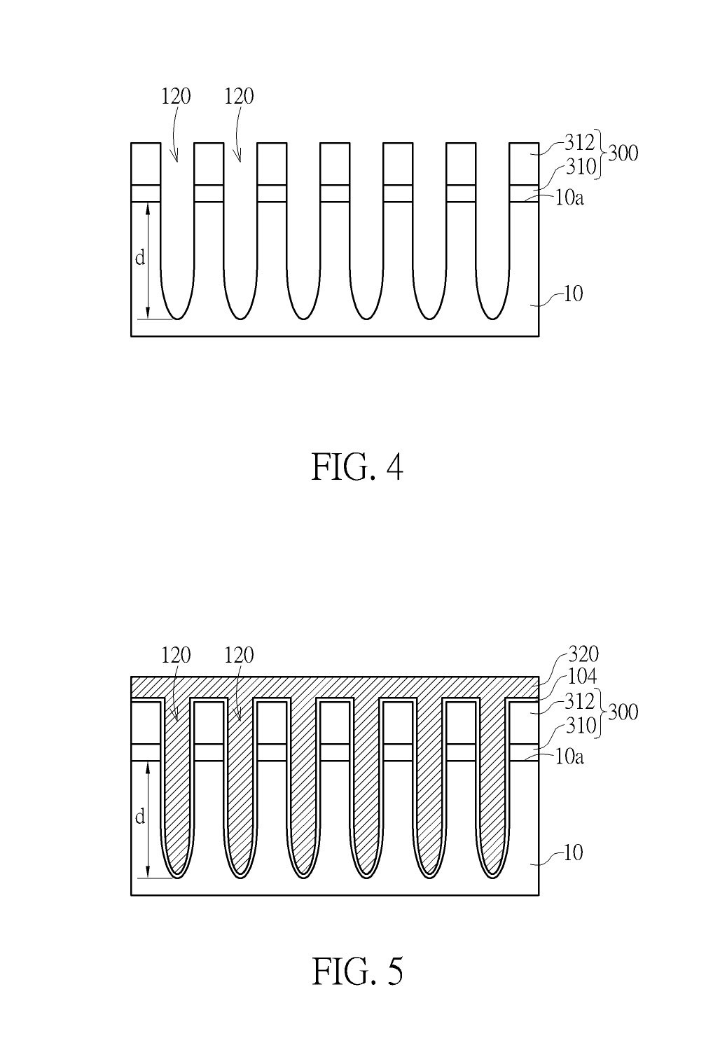

The present invention is also directed to forming the memory device having buried wordlines disclosed herein. FIG. 4 to FIG. 8 are schematic, cross-sectional views taken along line I-I′ depicting an exemplary method for fabricating the memory device having buried wordlines disclosed herein, wherein like numeral numbers designate like regions, layers or elements.

As shown in FIG. 4, a substrate 10 such as a semiconductor substrate or a silicon substrate is provided. A hard mask stack 300 may be formed on the main surface 10a of the substrate 10. According to the illustrative embodiment, the hard mask stack 300 may comprise a silicon oxide pad layer 310 and a silicon nitride layer 320, but not limited thereto. A lithographic process and a dry etching process are carried out to form a plurality of wordline trenches 120 in the substrate 10. Each of the wordline trenches 12 has a trench depth d below the main surface 10a of the substrate 10. It is to be understood that the formation of the plurality of wordline trenches 120 may be implemented after the formation of the active areas 100. As explained above, each active area 100 may be penetrated by two buried wordlines 12 and may be a dual bit active area.

As shown in FIG. 5, a gate dielectric layer 104 is deposited on the substrate 10. The gate dielectric layer 104 conformally covers the hard mask stack 300 and interior surfaces of the wordline trenches 120. After forming the gate dielectric layer 104, a conductive layer 320 is deposited on the gate dielectric layer 104. The wordline trenches 12 are completely filled with the gate dielectric layer 104 and the conductive layer 320. According to the illustrative embodiment, the conductive layer 320 may comprise TiN or W, but not limited thereto. It is to be understood that other metals or conductive materials may be used.

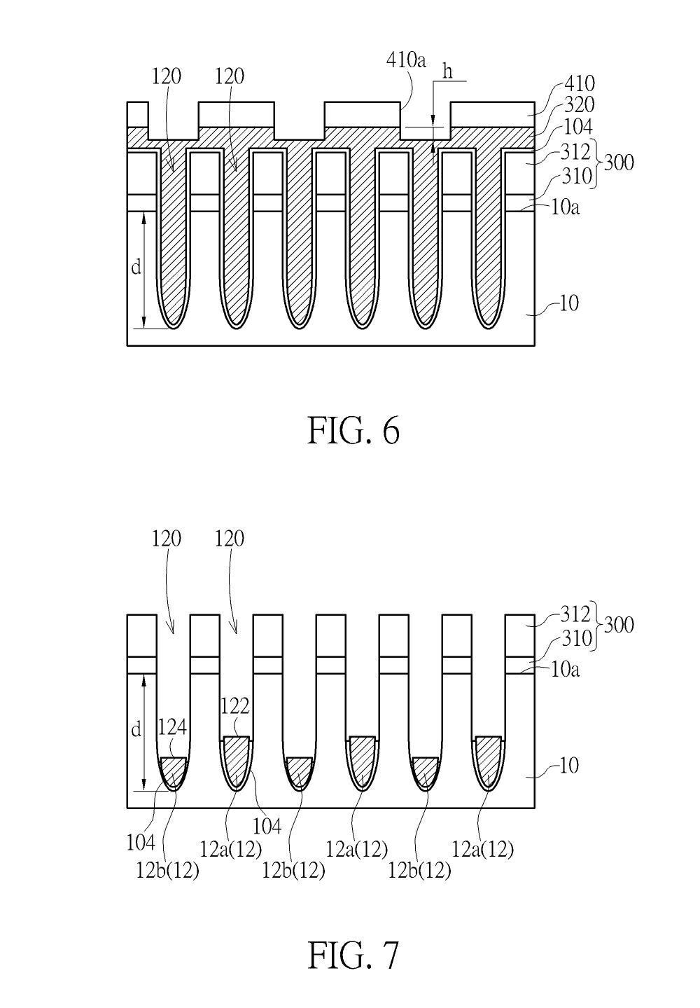

As shown in FIG. 6, a patterned photoresist layer 410 is then formed on the conductive layer 320. The patterned photoresist layer 410 comprises a plurality of openings 410a exposing predetermined portions of the conductive layer 320. The openings 410a may be referred to as localized recess gate (LRG) openings that are used to define the thinner portion 12b of each buried wordline 12.

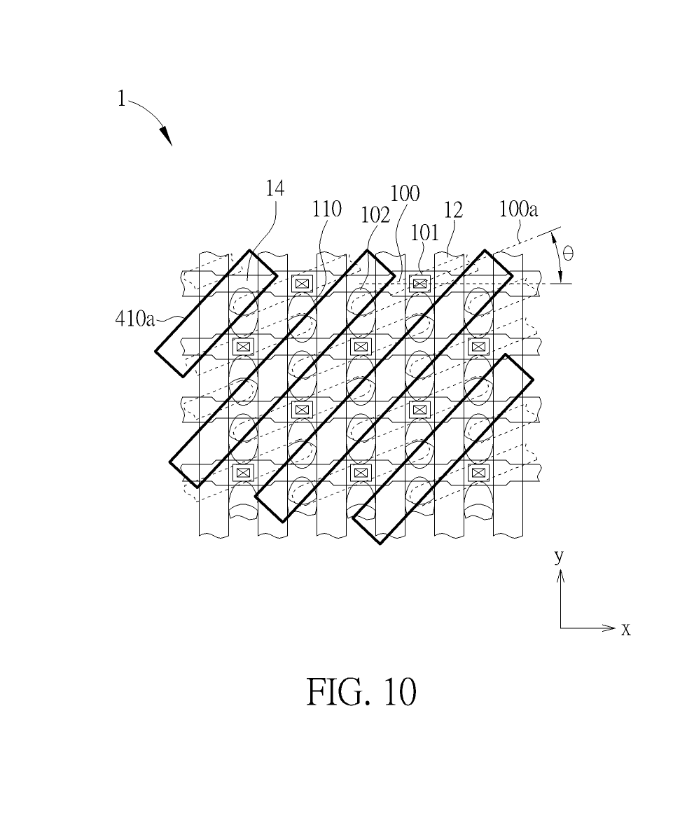

According to the illustrative embodiment, as shown in FIG. 9, the LRG openings may be staggered contact pattern. In FIG. 9, the LRG openings expose the conductive layer 320 between two ends of two adjacent active areas 100. According to another embodiment, as shown in FIG. 10, the LRG openings may be line-shaped pattern. The line-shaped LRG opening may extend at an angle relative to the reference x-axis, for example, 45 degree, in order to expose the desired regions of the conductive layer 320 between two ends of two adjacent active areas 100.

Subsequently, an LRG dry etching process is performed to recess the exposed portions of the conductive layer 320 to a predetermined depth h, as indicated in FIG. 6. The predetermined depth h determines the step height between the thicker portion 12a and thinner portion 12b of each buried wordline 12. For example, the predetermined depth h may range between 10 and 40 nm. After the LRG dry etching process is complete, the remaining patterned photoresist layer 410 is stripped off.

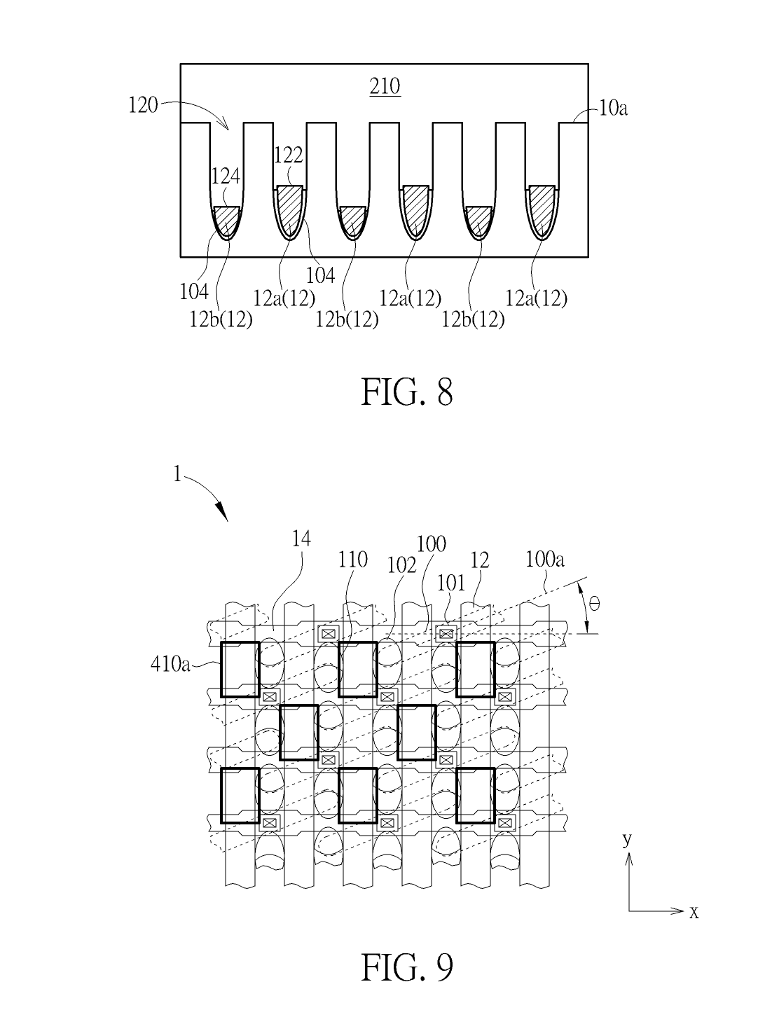

As shown in FIG. 7, a subsequent dry etching process is then performed to etch the conductive layer 320 in a blanket manner, thereby forming buried wordlines 12 comprising at least two successive and continuous thicker portion 12a and thinner portion 12b. The thicker portion 12a has a thickness that is greater than that of the thinner portion 12b. A plurality of thicker portion 12a and the thinner portion 12b are continuously and repeatedly arranged in each of the wordline trenches 120 to thereby constitute each of the buried wordlines 12.

The thicker portion 12a has a substantially flat top surface 122 and the thinner portion 12b has a substantially flat top surface 124. According to the illustrative embodiment, the top surface 122 is in a higher horizontal level than the top surface 124. According to the illustrative embodiment, both of the top surface 122 and the top surface 124 are lower than the main surface 10a of the silicon substrate 10. Subsequently, the exposed gate dielectric layer 104 is removed.

As shown in FIG. 8, after forming the buried wordlines 12, the hard mask stack 300 is removed. A dielectric layer 210 is then deposited to fill the wordline trenches 120. Thereafter, digitlines, contacts, and capacitors may be formed using known processing steps and techniques, e.g., deposition, etching, and photolithography.

Those skilled in the art will readily observe that numerous modifications and alterations of the device and method may be made while retaining the teachings of the invention. Accordingly, the above disclosure should be construed as limited only by the metes and bounds of the appended claims.

1. A memory device, comprising:
a substrate having thereon a plurality of active areas that are isolated from one another by a shallow trench isolation (STI) region;
a plurality of digitlines arranged along a first direction on the substrate; and
a plurality of buried wordlines arranged in wordline trenches in the substrate along a second direction that is orthogonal to the first direction, wherein the wordline trenches have the same trench depth below a main surface of the substrate, wherein each of the buried wordlines comprises a plurality of top surfaces, and wherein said top surfaces of each of the buried wordlines are alternately and repeatedly in a higher horizontal level and a lower horizontal level along the second direction.

2. The memory device according to claim 1, wherein each of the active areas has an approximately longitudinal centerline that is positioned at an angle θ relative to first direction.

3. The memory device according to claim 2, wherein the angle θ ranges between 20-80 degrees.

4. The memory device according to claim 1, wherein each of the active areas is penetrated by two of the buried wordlines and is a dual bit active area.

5. The memory device according to claim 4, wherein a single digitline contact is positioned on a common source region between the two of the buried wordlines.

6. The memory device according to claim 5 further comprising two storage contacts positioned on respective drain regions at distal ends of each of the active areas to electrically couple to respective capacitors.

7. The memory device according to claim 1 further comprising a gate dielectric layer between each of the buried wordline and the substrate.

8-10. (canceled)

11. The memory device according to claim 1, wherein each of wordline's top surface in the lower horizontal level is arranged between two ends of adjacent two of said active areas.

12. The memory device according to claim 1, wherein each of the buried wordlines has a battlement-shaped profile in cross-section observation.

13. The memory device according to claim 1, wherein the buried wordlines are composed of titanium nitride (TiN), tungsten (W), or a combination thereof.
